(19) United States
(12) Patent Application Publication
(10) Pub. No.: US 2025/0338691 A1
(43) Pub. Date: Oct. 30, 2025

(54) DISPLAY DEVICE, ELECTRONIC DEVICE AND METHOD OF MANUFACTURING DISPLAY DEVICE

(71) Applicant: Samsung Display Co., LTD., Yongin-si (KR)

(72) Inventor: Young-Geun CHO, Yongin-si (KR)

(21) Appl. No.: 19/043,833

(22) Filed: Feb. 3, 2025

(30) Foreign Application Priority Data
Apr. 26, 2024 (KR) 10-2024-0056176

(51) Int. Cl. H10H 29/80; H10H 29/01

(52) U.S. Cl. CPC H10H 29/8322; H10H 29/032; H10H 29/8321

(57) ABSTRACT

A display device according to an embodiment may include: a substrate; a first electrode disposed on the substrate; an emission layer disposed on the first electrode; a second electrode disposed on the emission layer; and a metal pattern portion disposed on the second electrode.

This application claims priority to Korean Patent Application No. 10-2024-0056176, filed on Apr. 26, 2024, and all the benefits accruing therefrom under 35 U.S.C. § 119, the content of which in its entirety is herein incorporated by reference.

### BACKGROUND

### Technical Field

The present disclosure relates to a display device, electronic device and a method for manufacturing the display device.

### (b) Description of the Related Art

An emitting element is a device that forms an exciton by combining a hole supplied from an anode and an electron supplied from a cathode within an emission layer formed between the anode and the cathode, and emits light as excitons are stabilized.

The emitting element has various merits such as, for example, a wide viewing angle, a fast response speed, a thin thickness, and low power consumption, and thus the emitting element is widely applied to various electrical and electronic devices such as, for example, televisions, monitors, and mobile phones.

### SUMMARY

Embodiments are provided to increase luminous efficiency and emission efficiency of a light emitting element.

A display device according to an embodiment may include: a substrate; a first electrode disposed on the substrate; an emission layer disposed on the first electrode; a second electrode disposed on the emission layer; and a metal pattern portion disposed on the second electrode.

A thickness of the metal pattern portion may be about 5 nm to about 800 nm.

The metal pattern portion may contain at least one of silver (Ag), copper (Cu), platinum (Pt), gold (Au), and palladium (Pd).

The metal pattern portion may be randomly formed on an entire surface of the second electrode.

The metal pattern portion may be formed directly on a surface of the second electrode and disposed integrated with the second electrode.

A method of manufacturing a display device according to an embodiment may include: forming a first electrode on a substrate; forming an emission layer on the first electrode; forming a second electrode on the emission layer; applying a metal organic decomposition ink on a surface of the second electrode; and forming a metal pattern portion disposed on the second electrode by reducing a metal from the applied metal organic decomposition ink.

The metal organic decomposition ink may include a metal ion and an organic solvent.

A metal of the metal ion may contain at least one of silver (Ag), copper (Cu), platinum (Pt), gold (Au), and palladium (Pd).

The organic solvent may contain at least one of isopropanol, butanol, acetone, ethanol, and toluene.

The forming the metal pattern portion may include randomly forming the metal pattern portion on an entire surface of the second electrode.

The forming the metal pattern portion may include placing a mask on the second electrode and emitting light.

The forming the metal pattern portion may include emitting a laser beam.

The applying the metal organic decomposition ink may include at least one of an inkjet process, a spray process, a dispensing process, a screen printing process, and a dipping process.

The reducing the metal may include at least one of high temperature oven curing, UV curing, electric curing, and laser curing.

The method may further include drying after the reducing the metal.

The drying may include at least one of room temperature drying, high temperature oven drying, infrared drying, and vacuum-drying.

A method of manufacturing a display device according to an embodiment may include: forming a first electrode on a substrate; applying a metal organic decomposition ink on a surface of the first electrode; forming a metal pattern portion disposed on the first electrode by reducing a metal from the applied metal organic decomposition ink; forming an emission layer on the metal pattern portion; and forming a second electrode on the emission layer.

The metal organic decomposition ink may include a metal ion and an organic solvent.

The forming the metal pattern portion may include randomly forming the metal pattern portion on an entire surface of the first electrode.

The forming the metal pattern portion may include placing a mask on the second electrode and emitting light.

According to the embodiments, internal light loss occurring through the waveguide mode and surface plasmon may be reduced by forming a metal pattern portion, and luminous efficiency of the emitting element may be improved through the resonance effect and scattering effect of light. In some aspects, the shape of the metal pattern portion may be adjusted by adjusting the composition of the metal organic decomposition ink. During an organic light-emitting diode (OLED) or quantum dot organic light-emitting diode (QD-OLED) inkjet process, when organic and inorganic ink is applied by forming a metal pattern, the metal pattern increases the spreadability of the organic and inorganic ink and supports uniform drying of particles during the drying process after applying ink. The inkjet processes described herein provide a simple and economical process compared to existing methods.

### BRIEF DESCRIPTION OF THE DRAWINGS

FIG. 1 is a cross-sectional view of some component of a display device according to an embodiment.

FIG. 2 is a top plan view of some component according to according to an embodiment.

FIG. 3 is a flowchart of a manufacturing method of some constituent elements of a display device according to according to an embodiment.

FIG. 4 to FIG. 8 are cross-sectional views of a manufacturing process of some constituent elements of a display device according to according to an embodiment.

FIG. 9 is a cross-sectional view of some constituent elements of a display device according to another embodiment.

FIG. 10 is a top plan view of the constituent elements of the display device according to the other embodiment.

FIG. 11 is a flowchart of a manufacturing method of some constituent elements of a display device according to another embodiment.

FIGS. 12 to 15 are cross-sectional views of a manufacturing process of some constituent elements of a display device according to the other embodiment.

FIG. 16 is a block diagram of an electronic device according to some embodiments.

FIG. 17 shows schematic diagrams of electronic devices according to various embodiments.

### DETAILED DESCRIPTION

Hereinafter, the present disclosure will be described more fully hereinafter with reference to the accompanying drawings, in which embodiments of the present disclosure are illustrated. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In some aspects, since the size and thickness of each component illustrated in the drawing are arbitrarily indicated for better understanding and ease of description, embodiments of the present disclosure are not necessarily limited to the drawings. In the drawings, the thickness of layers, films, panels, regions, other components, or the like may be exaggerated for clarity. In the drawings, the thickness of layers, films, panels, regions, other components, or the like may be exaggerated for clarity.

It will be understood that when an element such as, for example, a layer, film, region, or substrate is referred to as being “on” another element, it may be directly on the other element or intervening elements may also be present. In contrast, when an element is referred to as being “directly on” another element, there are no intervening elements present. Further, throughout the specification, the word “on” a target element may be understood to mean positioned above, below, or beside the target element, and will not necessarily be understood to mean positioned “at an upper side” based on a direction opposite to the direction of gravity.

In some aspects, unless explicitly described to the contrary, the word “comprise”, and variations such as, for example, “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.”

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example.

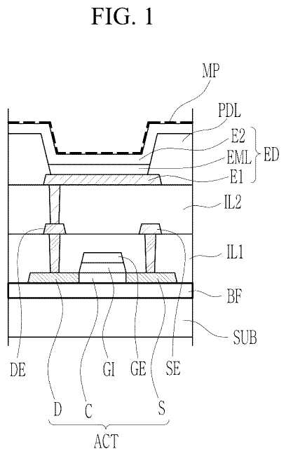

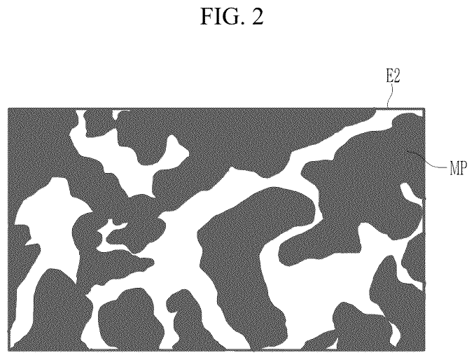

Hereinafter, referring to FIG. 1 and FIG. 2, a display device according to an embodiment will be described. FIG. 1 is a cross-sectional view of some component of a display device according to an embodiment, and FIG. 2 is a top plan view of some component according to according to an embodiment.

Referring to FIG. 1, a display device according to an embodiment includes a substrate SUB. The substrate SUB may include a flexible material such as, for example, plastic that may be twisted, bent, folded, or rolled, or may include a rigid substrate.

A buffer layer BF may be disposed on the substrate SUB. Depending on embodiments, the buffer layer BF may be omitted. The buffer layer BF may include silicon nitride (SiNₓ), silicon oxide (SiO₂), or silicon oxynitride. The buffer layer BF is disposed between the substrate SUB and a semiconductor layer ACT, and improves the characteristics of polycrystalline silicon by blocking impurity from the substrate SUB during a crystallization process to form polycrystalline silicon and alleviates the stress of the semiconductor layer ACT formed on the buffer layer BF by planarizing the substrate SUB.

The semiconductor layer ACT is disposed on the buffer layer BF. The semiconductor layer ACT may be formed of polycrystalline silicon or an oxide semiconductor. The semiconductor layer ACT may include a channel region C, a source region S, and a drain region D. The source region S and the drain region D are respectively disposed at both sides of the channel region C. The channel region C is an intrinsic semiconductor with undoped impurity, and the source region S and the drain region D are impurity semiconductors with doped conductive impurity. The semiconductor layer ACT may be formed of an oxide semiconductor, and in this case, a separate protective layer (not illustrated) may be added to protect the oxide semiconductor material, which is vulnerable to external environments such as, for example, high temperature environments.

A gate insulating layer GI is disposed on the semiconductor layer ACT. The gate insulating layer GI may be single-layered or multi-layered, including at least one of silicon nitride (SiNₓ), silicon oxide (SiO₂), and silicon oxynitride.

The gate electrode GE is disposed on the gate insulating layer GI. The gate electrode GE may be a multilayer in which a metal layer containing any one of copper (Cu), a copper alloy, aluminum (AI), an aluminum alloy, molybdenum (Mo), and a molybdenum alloy is stacked.

An interlayer insulation layer IL1 is disposed on the gate electrode GE and the gate insulating layer GI. The interlayer insulation layer IL1 may include silicon nitride (SiNx), silicon oxide (SiO₂), or silicon oxynitride. An opening exposing the source region S and the drain region D, respectively, is positioned on the interlayer insulation layer IL1.

The source electrode SE and the drain electrode DE are disposed on the interlayer insulation layer IL1. The source electrode SE and the drain electrode DE are respectively connected to the source region S and the drain region D of the semiconductor layer ACT through the opening formed in the interlayer insulation layer IL1.

A protective layer IL2 is disposed on the interlayer insulation layer IL1, the source electrode SE, and the drain electrode DE. Since the protective layer IL2 covers and planarizes the interlayer insulation layer IL1, the source electrode SE, and drain electrode DE, a first electrode E1 may be formed on the protective layer IL2 without steps. The protective layer IL2 may be formed of organic materials such as, for example, polyacrylates resin, polyimides resin, or a laminated film of organic materials and inorganic materials.

The first electrode E1 is disposed on the protective layer IL2. The first electrode E1 is electrically connected with the drain electrode DE through the opening of the protective layer IL2.

A pixel definition layer PDL may be disposed on the protective layer IL2 and the first electrode E1, and the pixel definition layer PDL may include a pixel opening defining a light emission region while overlapping the first electrode E1. The pixel definition layer PDL may include an organic material such as, for example, polyacrylates resin, polyimides resin, and the like, or a silica-based inorganic material. The pixel opening may have a planar shape that is substantially the same as a planar shape of the first electrode E1, and may have a rhombus or an octagonal shape substantially the same as a rhombus on a plane, but is not limited thereto and may have any shape such as, for example, a quadrangle or polygon.

An emission layer EML is disposed on the first electrode E1 that overlaps the pixel opening. The emission layer EML may be formed of a low molecular organic material or polymer organic material such as, for example, poly 3,4-ethylenedioxythiophene (PEDOT). In some aspects, the emission layer EML may be a multilayer including one or more of a hole injection layer (HIL), a hole transporting layer (HTL), an electron transporting layer (ETL), and an electron injection layer (EIL).

The emission layer EML may mostly be disposed within the pixel opening, and may also be disposed on a side or above the pixel definition layer PDL. The specification illustrates an embodiment in which the emission layer EML is disposed within the opening while not overlapping other elements, but embodiments of the present disclosure are not limited thereto, and the emission layer EML may continuously overlap with an entire surface of the substrate SUB.

The second electrode E2 is disposed on the emission layer EML. The second electrode E2 may be disposed across a plurality of pixels and may receive a common voltage through a common voltage transfer portion (not illustrated) in a non-display area.

A metal pattern portion MP may be disposed on the second electrode E2.

Hereinafter, the metal pattern portion MP will be described in detail with reference to FIG. 1 and FIG. 2. FIG. 2 is a top plan view of some constituent elements of the embodiment.

The metal pattern portion MP may have a thickness of about 5 nm to about 800 nm. The metal pattern portion MP may be a fine pattern. The metal pattern portion MP is formed directly on a surface of the second electrode E2 and may be disposed integrated with the second electrode E2. In some aspects, as illustrated in FIG. 2, the metal pattern portion MP may be randomly formed in an entire surface of the second electrode E2. However, embodiments of the present disclosure are not limited thereto, and a certain pattern may be repeated and formed regularly. Expressed another way, the metal pattern portion MP may be formed of a certain pattern, in which the certain pattern is repeated and formed regularly (e.g., according to a predetermined spacing, a predetermined quantity, in a predetermined direction, and the like).

The metal pattern portion MP may include at least one of silver (Ag), copper (Cu), platinum (Pt), gold (Au), and palladium (Pd), but is not limited thereto and any material that may be reduced to a metal by reducing organic decomposition ink (MOD), which will be described later, may be used. In particular, the luminous efficiency of the light emitting element may be further improved using a highly reflective material such as, for example, silver (Ag).

When an angle of light incident on the surface of the second electrode E2 exceeds a critical angle, the light may not escape the material and is totally reflected inside, causing the light to leak out to the side, which is called the waveguide mode. In an example in which forming the metal pattern portion MP on the surface of the second electrode E2, the light incident on the surface of the second electrode E2 may be prevented from leaking to the side due to the waveguide mode.

When an electromagnetic wave from the outside is incident on a metal surface at the interface of two media with different refractive indices, the phenomenon in which charged particles excited on the metal surface vibrate is called surface plasmon. The surface plasmon is generated when electrons on the metal surface collectively vibrate due to the resonance phenomenon of the electron field incident on the metal surface. In an example in which forming the metal pattern portion MP on the surface of the second electrode E2, a resonance phenomenon is induced between the surface plasmon generated on the surface of the second electrode E2 and the incident light, and the surface plasmon generated on the surface of the second electrode E2 may be extracted into light.

In some aspects, reflection of the light incident on the second electrode E2 when the metal pattern portion MP is formed to be protruded may be prevented and light incident from various directions may be efficiently collected and radiated, thereby increasing the uniformity of light.

Referring back to FIG. 1, the first electrode E1, the emission layer EML, and the second electrode E2 may form an emitting element ED. Here, the first electrode E1 may be an anode, which is a hole injection electrode, and the second electrode E2 may be a cathode, which is an electron injection electrode. Holes and electrons are injected into the emission layer EML from the first electrode E1 and the second electrode E2, respectively, and light emitting occurs when the exciton combined with the injected hole and electron falls from the exited state to the ground state.

In some embodiments, the emitting diode according to an embodiment may include a plurality of emission units. Each emission unit may include an emission layer EML. That is, the emission element ED according to an embodiment may include a plurality of emission layers EML. The emission element ED may be a light emitting element with a tandem structure. The plurality of emission layers EML may emit the same light or different lights. As an example, the emission element ED may emit a mixture of green light and blue light, or may emit blue light.

Therefore, according to the present disclosure, the metal pattern portion MP is formed on the second electrode E2 such that internal light loss occurring through the waveguide mode and surface plasmon may be reduced, and the luminous efficiency of the light emitting element may be improved through the resonance effect and scattering of light.

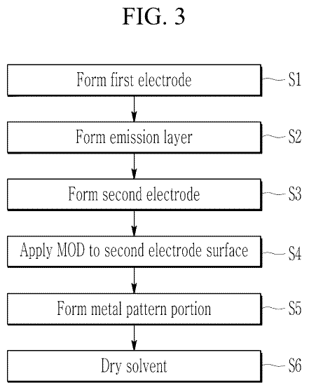

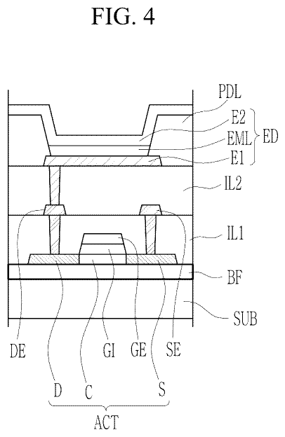

Hereinafter, referring to FIG. 3 to FIG. 8, a method of manufacturing a display device according to according to an embodiment will be described. FIG. 3 is a flowchart of a manufacturing method of some constituent elements of a display device according to according to an embodiment. FIG. 4 to FIG. 8 are cross-sectional views of a manufacturing process of some constituent elements of a display device according to according to an embodiment.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

With reference to FIG. 3, a method of manufacturing the display device according to the present embodiment includes forming the first electrode E1 (at S1), forming the emission layer EML (at S2), forming the second electrode E2 (at S3), applying a metal organic decomposition ink (MOD) to the surface of the second electrode E2 (at S4), forming the metal pattern portion MP (at S5), and drying a solvent (at S6).

As illustrated in FIG. 4, the buffer layer BF is disposed on the substrate, and the semiconductor layer ACT is disposed on the buffer layer BF. The gate insulating layer GI is disposed on the semiconductor layer ACT. The gate electrode GE is disposed on the gate insulating layer GI. The interlayer insulation layer IL1 is disposed on the gate electrode GE and the gate insulating layer GI. The source electrode SE and the drain electrode DE are disposed on the interlayer insulation layer IL1. The protective layer IL2 is disposed on the interlayer insulation layer IL1, the source electrode SE, and the drain electrode DE.

The method may include forming the first electrode E1 on the protective layer IL2 (at S1). In an example in which the first electrode E1 is formed, the method may include forming the emission layer EML on the first electrode E1 (at S2). In an example in which the emission layer EML is formed, the method may include forming the second electrode E2 (at S3).

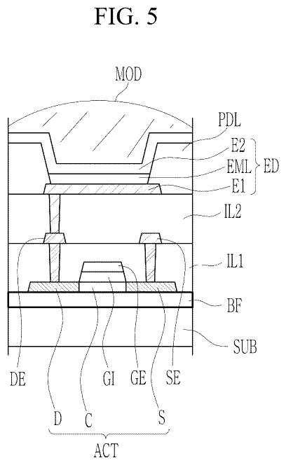

Next, as illustrated in FIG. 5, the method may include applying the metal organic decomposition ink MOD on the surface of the second electrode E2 (at S4). The metal organic decomposition ink MOD may be applied using at least one of an inkjet process, a spray process, a dispensing process, a screen printing process, and a dipping process.

The inkjet process uses ink droplets to spray ink onto the second electrode E2 according to a fixed density, and the inkjet process may generate precise patterns by operating in a non-contact manner. The spray process sprays ink in the form of fine particles in association with coating an element with the ink, thereby forming a uniform coating layer. The dispensing process uses a dispenser to precisely place a set amount of ink at a specific position. The screen printing process is a method of delivering ink to an electrode through a screen, and the screen printing process supports the use of ink with high viscosity. The dipping process is a simple and economical method of dipping the substrate in an ink solution and then slowly pulling the substrate out, thereby coating the substrate. Aspects of applying the metal organic decomposition ink MOD to an electrode as supported by embodiments of the present disclosure are not limited to the example methods provided herein, and various application methods may be applied.

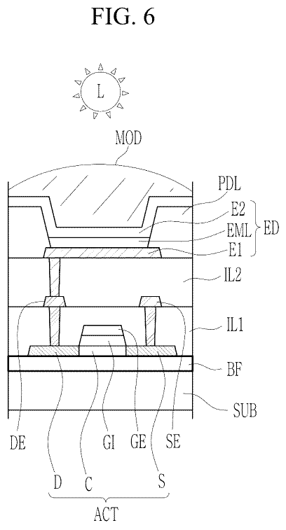

The method may include forming the metal pattern portion MP by reducing metal in the applied metal organic decomposition ink MOD (at S5). In the forming the metal pattern portion MP, as illustrated in FIG. 6, the method may include curing the metal organic decomposition ink MOD by irradiating the metal organic decomposition ink MOD with light L. The curing includes at least one of high temperature oven curing, UV curing, electric curing, and laser curing, and may not be limited thereto if metal may be reduced and precipitated.

In some embodiments, the method may include drying (at S6) after the reducing of the metal. The drying may remove a solvent (e.g., an organic solvent) of the metal organic decomposition ink MOD. The drying may include at least one of room temperature drying, high temperature oven drying, infrared drying, and vacuum-drying. Aspects of removing a solvent of the metal organic decomposition ink MOD as supported by embodiments of the present disclosure are not limited to the example methods provided herein, and various methods may be used.

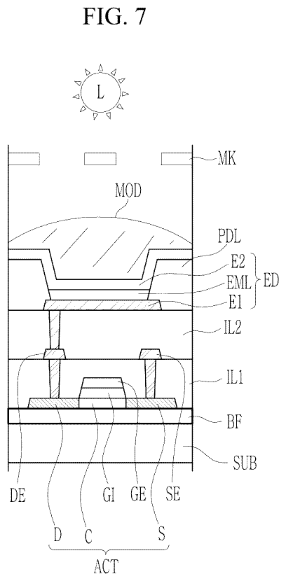

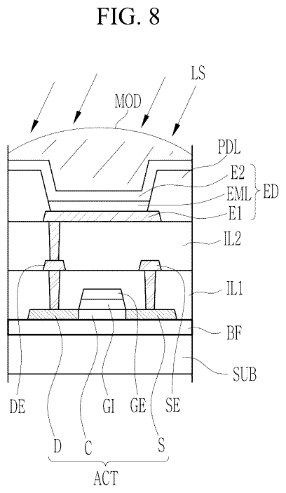

In some embodiments, the method (at S5) may include randomly forming the metal pattern portion MP on the surface of the second electrode E2 using the manufacturing method described herein. In forming the metal pattern portion MP, the manufacturing method may include placing a mask MK on the second electrode E2 and emitting the light L (e.g., such that some elements exposed by the mask MK are irradiated with the light L) as illustrated in FIG. 7. Additionally, or alternatively, the manufacturing method may include forming a specific pattern by emitting a laser beam LS as illustrated in FIG. 8.

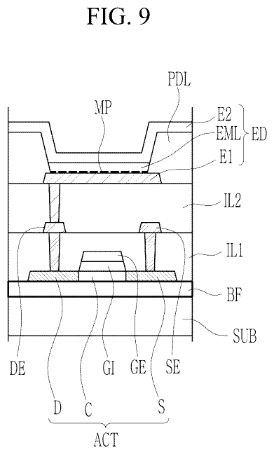

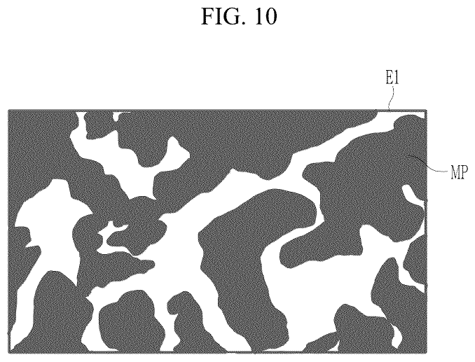

Hereinafter, a display device according to another embodiment will be described with reference to FIG. 9 and FIG. 10. FIG. 9 is a cross-sectional view of some constituent elements of a display device according to another embodiment, and FIG. 10 is a top plan view of the constituent elements of the display device according to the other embodiment. Descriptions of components that are the same as the components described herein will be omitted.

Referring to FIG. 9, a metal pattern portion MP may be disposed on a first electrode E1. An emission layer EML may be disposed on the first electrode E1 where the metal pattern portion MP is formed, and a second electrode E2 may be disposed on the emission layer EML.

Hereinafter, the metal pattern portion MP will be described in detail with reference to FIG. 9 and FIG. 10. FIG. 10 is a top plan view of some constituent elements according to the other embodiment.

The metal pattern portion MP may have a thickness of about 5 nm to about 800 nm. The metal pattern portion MP may be a fine pattern. The metal pattern portion MP is formed directly on a surface of the first electrode E1 and may be disposed integrated with the first electrode E1. In some aspects, as illustrated in FIG. 8, the metal pattern portion MP may be randomly formed in an entire surface of the first electrode E1. However, embodiments of the present disclosure are not limited thereto, and a certain pattern may be repeated and formed regularly. Expressed another way, the metal pattern portion MP may be formed of a certain pattern, in which the certain pattern is repeated and formed regularly.

The metal pattern portion MP may include at least one of silver (Ag), copper (Cu), platinum (Pt), gold (Au), and palladium (Pd), but is not limited thereto and any material that may be reduced to a metal by reducing organic decomposition ink (MOD), which will be described later, may be used. In particular, the luminous efficiency of the light emitting element may be further improved using a highly reflective material such as, for example, silver (Ag).

As described herein, the organic decomposition ink MOD may include a metal ion (i.e., an atom of a metal that has lost one or more electrons) and an organic solvent. A metal of the metal ion may include at least one of silver (Ag), copper (Cu), platinum (Pt), gold (Au), and palladium (Pd), but is not limited thereto. The organic solvent may contain at least one of isopropanol, butanol, acetone, ethanol, and toluene, but is not limited thereto.

When an angle at which light is incident on the surface of the first electrode E1 exceeds a critical angle (e.g., a threshold angle), the light may not escape the material and is totally reflected inside, causing the light to leak out to the side, which is called the waveguide mode. In an example of forming the metal pattern portion MP on the surface of the first electrode E1, the light incident on the surface of the first electrode E1 may be prevented from leaking to the side due to the waveguide mode.

In some aspects, based on the formation of the metal pattern portion MP as described herein, the metal pattern portion MP may protrude, and the reflection of the light incident on the first electrode E1 may be prevented and light incident from various directions may be efficiently collected and radiated, thereby increasing the uniformity of light.

Therefore, according to the present disclosure, the metal pattern portion MP may be formed on the first electrode E1 such that internal light loss occurring through the waveguide mode is reduced, and the luminous efficiency of the light emitting element may be improved through the scattering of light.

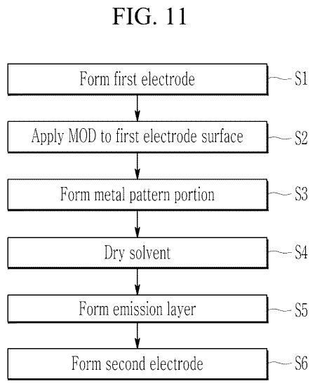

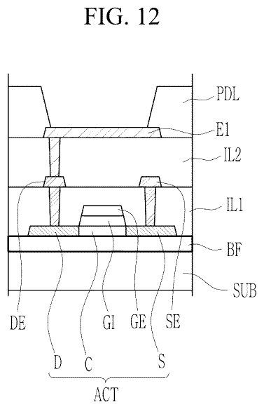

Hereinafter, referring to FIGS. 11 to 15, a method of manufacturing a display device according to according to another embodiment will be described. FIG. 11 is a flowchart of a manufacturing method of some constituent elements of a display device according to another embodiment. FIGS. 12 to 15 are cross-sectional views of a manufacturing process of some constituent elements of a display device according to the other embodiment.

With reference to FIG. 11, a method of manufacturing the display device according to according to the other embodiment includes forming the first electrode E1 (at S1), applying a metal organic decomposition ink (MOD) to the surface of the first electrode E1 (at S2), forming the metal pattern portion MP (at S3), drying a solvent (at S4), forming the emission layer EML (at S5), and forming the second electrode E2 (at S6).

First, as illustrated in FIG. 12, the method may include forming the first electrode E1 (at S1). In this case, the buffer layer BF is disposed on the substrate SUB, and the semiconductor layer ACT is disposed on the buffer layer BF. The gate insulating layer GI is disposed on the semiconductor layer ACT. The gate electrode GE is disposed on the gate insulating layer GI. The interlayer insulation layer IL1 is disposed on the gate electrode GE and the gate insulating layer GI. The source electrode SE and the drain electrode DE are disposed on the interlayer insulation layer IL1. The protective layer IL2 is disposed on the interlayer insulation layer IL1, the source electrode SE, and the drain electrode DE. The first electrode E1 may be formed on the protective layer IL2.

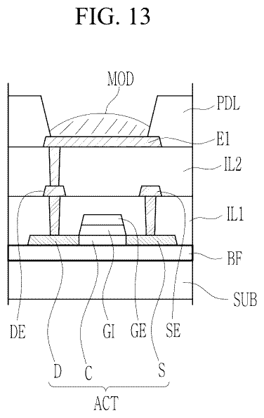

As illustrated in FIG. 13, the method may include applying the metal organic decomposition ink MOD to the first electrode E1 (S2). In this case, for example, the metal organic decomposition ink MOD may be applied using at least one of an inkjet process, a spray process, a dispensing process, a screen printing process, and a dipping process.

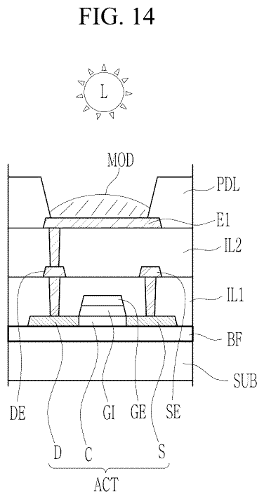

The method may include forming the metal pattern portion MP by reducing metal in the applied metal organic decomposition ink MOD (at S3). In the forming the metal pattern portion MP, as illustrated in FIG. 14, the method may include curing the metal organic decomposition ink MOD by irradiating the metal organic decomposition ink MOD with light L. The curing includes at least one of high temperature oven curing, UV curing, electric curing, and laser curing, and may not be limited thereto if metal may be reduced and precipitated.

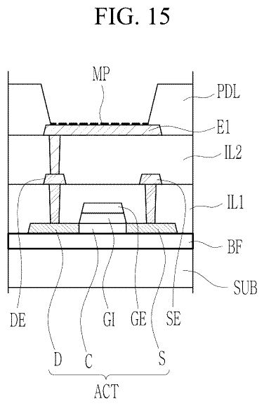

The method may include performing drying (at S4) after the reducing of the metal. The drying may remove a solvent (e.g., an organic solvent) of the metal organic decomposition ink MOD. The drying may include at least one of room temperature drying, high temperature oven drying, infrared drying, and vacuum-drying. Aspects of removing a solvent of the metal organic decomposition ink MOD as supported by embodiments of the present disclosure are not limited to the example methods provided herein. Accordingly, as illustrated in FIG. 15, the metal pattern portion MP may be formed on the surface of the first electrode E1.

In some embodiments, the method (at S3) may include randomly forming the metal pattern portion MP on the surface of the first electrode E1 using the manufacturing method described herein. In forming the metal pattern portion MP, the manufacturing method may include placing a mask on the first electrode E1 and emitting light (e.g., irradiating one or more elements exposed by the mask with the emitted light). Additionally, or alternatively, the manufacturing method may include forming a specific pattern by emitting a laser beam (e.g., irradiating one or more elements with the emitted laser beam).

As illustrated in FIG. 9, the method may include forming the emission layer EML on the first electrode E1 where the metal pattern portion MP is formed (at S5). Next, the method may include forming the second electrode SE2 on the emission layer EML (at S6). In this case, when the emission layer EML and the second electrode E2 are formed through a deposition process, the shape of the metal pattern portion MP of the first electrode E1 may also be formed on the emission layer EML and the second electrode E2.

A display device according to an embodiment may be applied to various electronic devices. An electronic device according to an embodiment may include the display device, and may further include modules or devices having additional functions other than the display device.

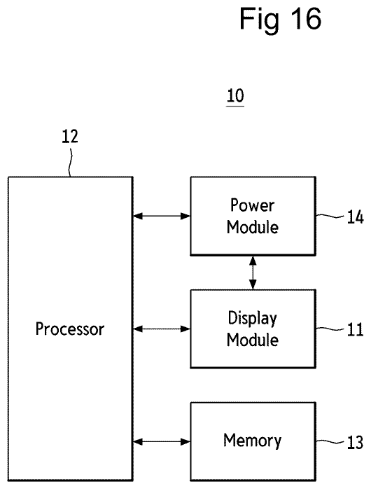

FIG. 16 is a block diagram of an electronic device according to an embodiment. Referring to FIG. 16, the electronic device 1000 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 1000.

At least one of components of the electronic device 1000 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 1000 that are not part of the display device.

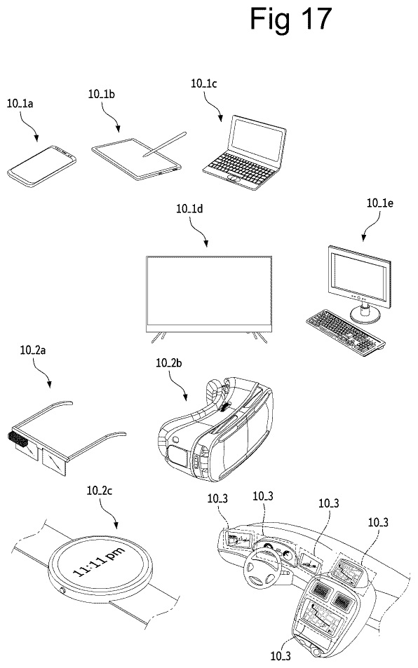

FIG. 17 shows schematic diagrams of electronic devices according to various embodiments.

Referring to FIG. 17, various electronic devices with the display device according to the embodiments may include not only image display electronic devices such as smartphones 1000_1a, tablet PCs 1000_1b, laptops 1000_1c, TVs 1000_1d, desktop monitors 1000_1e, but also wearable electronic devices with display modules such as smart glasses 1000_2a, head-mounted displays 1000_2b, smart watches 1000_2c, as well as automotive electronic devices with display modules 1000_3 such as those placed on car dashboards, center fascias, CID (Center Information Display), room mirror displays, and so on.

While aspects of the present disclosure have been described in connection with what is presently considered to be practical embodiments, it is to be understood that the aspects of the present disclosure are not limited to the disclosed embodiments. On the contrary, aspects of the present disclosure are intended to cover various modifications and equivalent arrangements included within the spirit and scope of the appended claims.

What is claimed is:

1. A display device comprising:
a substrate;
a first electrode disposed on the substrate;
an emission layer disposed on the first electrode;
a second electrode disposed on the emission layer; and
a metal pattern portion disposed on the second electrode.

2. The display device of claim 1, wherein a thickness of the metal pattern portion is about 5 nm to about 800 nm.

3. The display device of claim 1, wherein the metal pattern portion contains at least one of silver (Ag), copper (Cu), platinum (Pt), gold (Au), and palladium (Pd).

4. The display device of claim 1, wherein the metal pattern portion is randomly formed on an entire surface of the second electrode.

5. The display device of claim 1, wherein the metal pattern portion is formed directly on a surface of the second electrode and disposed integrated with the second electrode.

6. A method of manufacturing a display device, comprising:
forming a first electrode on a substrate;
forming an emission layer on the first electrode;
forming a second electrode on the emission layer;
applying a metal organic decomposition ink on a surface of the second electrode; and
forming a metal pattern portion disposed on the second electrode by reducing a metal from the applied metal organic decomposition ink.

7. The method of claim 6, wherein the metal organic decomposition ink comprises a metal ion and an organic solvent.

8. The method of claim 7, wherein a metal of the metal ion contains at least one of silver (Ag), copper (Cu), platinum (Pt), gold (Au), and palladium (Pd).

9. The method of claim 7, wherein the organic solvent contains at least one of isopropanol, butanol, acetone, ethanol, and toluene.

10. The method of claim 6, wherein the forming the metal pattern portion comprises randomly forming the metal pattern portion on an entire surface of the second electrode.

11. The method of claim 6, wherein the forming the metal pattern portion comprises placing a mask on the second electrode and emitting light.

12. The method of claim 6, wherein the forming the metal pattern portion comprises emitting a laser beam.

13. The method of claim 6, wherein the applying the metal organic decomposition ink comprises at least one of an inkjet process, a spray process, a dispensing process, a screen printing process, and a dipping process.

14. The method of claim 6, wherein the reducing the metal comprises at least one of high temperature oven curing, UV curing, electric curing, and laser curing.

15. The method of claim 6, further comprising drying after the reducing the metal.

16. The method of claim 15, wherein the drying comprises at least one of room temperature drying, high temperature oven drying, infrared drying, and vacuum-drying.

17. An electronic device comprising:
a memory;
a processor executing an application stored in the memory; and
a display device comprising a display module outputting video information provided by the application, wherein
the display device comprising:
a substrate;
a first electrode disposed on the substrate;
an emission layer disposed on the first electrode;
a second electrode disposed on the emission layer; and
a metal pattern portion disposed on the second electrode.

18. The electronic device of claim 1, wherein a thickness of the metal pattern portion is about 5 nm to about 800 nm.

19. The electronic device of claim 1, wherein the metal pattern portion contains at least one of silver (Ag), copper (Cu), platinum (Pt), gold (Au), and palladium (Pd).

20. The electronic device of claim 1, wherein the metal pattern portion is randomly formed on an entire surface of the second electrode.
